(19) United States
(12) Patent Application Publication
(10) Pub. No.: US 2024/0153909 A1
(43) Pub. Date: May 9, 2024

(54) HOT VIA DIE ATTACH JETTING

(71) Applicant: MACOM Technology Solutions Holdings, Inc., Lowell, MA (US)

(72) Inventors: Novak Farrington, Felton, CA (US); Moses Chan, San Jose, CA (US)

(21) Appl. No.: 18/053,915

(22) Filed: Nov. 9, 2022

(51) Int. Cl. H01L 23/00

(52) U.S. Cl. CPC H01L 24/83; H01L 24/32; H01L 2224/32225; H01L 2224/8385

(57) ABSTRACT

Devices and methods including hot via die attach jetting are described. An example integrated circuit device includes a semiconductor substrate, vias extending from a top to a bottom surface of the substrate, and a metal layer on the bottom surface of the substrate. The metal layer includes a metal pad extending around a via opening at the bottom surface of the substrate. The metal pad is electrically isolated from a remainder of the metal layer. The device also includes one or more jet-dispensed dots of a conductive die attach adhesive material on the metal pad. Electrical connections made through the metal pad and jet-dispensed dots may be preferred as compared to wire bonds or flip chip approaches, particularly for RF input and output signals. The use of jet-dispensed dots can facilitate high-volume and automated process techniques.

### BACKGROUND

Many different types of packages are available for integrated semiconductor circuit devices formed on semiconductor die. Semiconductor packages are generally designed to protect and secure the integrated circuit devices and provide electrically conductive leads, as electrical contacts to the circuit devices. Such packages can be surface mounted, through-hole mounted, or inserted into printed circuit boards, as examples. The type, size, lead style, and materials of any given package can be chosen based on the components being housed and secured within them, as well as the application for the components. Among other considerations, certain packages may be better suited for high power and high frequency applications. For example, some packages exhibit less intrinsic capacitance, inductance, and other parasitic characteristics, and those types of packages may be better suited for high power and high frequency applications.

Integrated circuit devices and die can be electrically connected within device packages in a variety of ways. Wire bonding, for example, can be relied upon to provide electrical couplings between wire bond pads on the top surface of a semiconductor die and metal traces, wire frames, and other interconnects within the packages. Wire bonding is relatively cost-effective and flexible, although the use of wire bonds does carry certain disadvantages for some applications.

Flip chip packaging is another way to electrically connect an integrated circuit device or die within a package to a supporting substrate. Solder bumps or balls are deposited onto bond pads on the top surface of a semiconductor die as part of the flip chip packaging process. The semiconductor die is then flipped over and aligned with matching conductive trances or pads on a supporting substrate or other circuit. The assembly is then placed into an oven or otherwise heated, to reflow the solder bumps or balls and form electrical connections.

### SUMMARY

Devices and methods including hot via die attach jetting are described. An example integrated circuit device includes a semiconductor substrate, vias extending from a top to a bottom surface of the substrate, and a metal layer on the bottom surface of the substrate. The metal layer includes a metal pad extending around a via opening at the bottom surface of the substrate. The metal pad is electrically isolated from a remainder of the metal layer. The integrated circuit device can also include one or more jet-dispensed dots of a conductive die attach adhesive material on the metal pad. The integrated circuit device can also include a second jet-dispensed dot of a second conductive die attach adhesive material on the remainder of the metal layer.

In other aspects, a first diameter of the jet-dispensed dot on the metal pad can be different than a second diameter of the second jet-dispensed dot on the remainder of the metal layer. In other aspects, the jet-dispensed dot on the metal pad can include a first plurality of jet-dispensed dots on the metal pad, and the second jet-dispensed dot can include a second plurality of jet-dispensed dots on the remainder of the metal layer. In one example, the conductive die attach adhesive material has a viscosity of greater than 5 Pa·s and a thermal conductivity of greater than 1 W/mK.

In other aspects, the conductive die attach material of the jet-dispensed dot on the metal pad can be different than the second conductive die attach material of the second jet-dispensed dot on the remainder of the metal layer. In one example, the conductive die attach adhesive material has a viscosity of greater than 5 Pa·s and a thermal conductivity of greater than 1 W/mK.

In other aspects, an isolation street extends between the metal pad and a remainder of the metal layer, and the integrated circuit device further comprises a solder mask extending over at least part of the isolation street. The integrated circuit device can also include a solder bump on the remainder of the metal layer.

In another embodiment, a method for hot via coupling includes jet-dispensing a dot of a conductive die attach adhesive material on a metal pad of an integrated circuit device. The integrated circuit device includes a semiconductor substrate, a plurality of vias extending from a top surface of the semiconductor substrate to a bottom surface of the semiconductor substrate, and a metal layer on the bottom surface of the semiconductor substrate. The metal layer includes the metal pad extending around a via opening of one of the plurality of vias at the bottom surface of the semiconductor substrate. The metal pad is electrically isolated from a remainder of the metal layer at the bottom surface of the semiconductor substrate. In some cases, the method can include jet-dispensing a plurality of dots of the conductive die attach adhesive material on the metal pad.

The method can also include adhering a solder bump to the remainder of the metal layer or jet-dispensing a second dot of the conductive die attach adhesive material on the remainder of the metal layer. In another example, method can also include jet-dispensing a second dot of a second conductive die attach adhesive material on the remainder of the metal layer. The conductive die attach adhesive material of the dot on the metal pad can be different than the second conductive die attach adhesive material of the second dot on the remainder of the metal layer.

The method can also include positioning the integrated circuit device structure over a supporting substrate, such that the metal pad of the integrated circuit device structure is aligned for an electrical connection to a trace on the supporting substrate, and thermosetting the dot of a conductive die attach adhesive material.

In another example, a method for hot via coupling includes jet-dispensing a dot of a conductive die attach adhesive material on a metal pad of an integrated circuit device. The circuit device can include a metal layer on a bottom surface of a substrate. The metal layer can include the metal pad extending around a via opening at the bottom surface of the substrate, and the metal pad can be electrically isolated from a remainder of the metal layer.

The method can also include adhering a solder bump to the remainder of the metal layer or jet-dispensing a second dot of the conductive die attach adhesive material on the remainder of the metal layer. In another example, method can also include jet-dispensing a second dot of a second conductive die attach adhesive material on the remainder of the metal layer. The conductive die attach adhesive material of the dot on the metal pad can be different than the second conductive die attach adhesive material of the second dot on the remainder of the metal layer.

The method can also include positioning the integrated circuit device structure over a supporting substrate, such that the metal pad of the integrated circuit device structure is aligned for an electrical connection to a trace on the supporting substrate, and thermosetting the dot of a conductive die attach adhesive material.

Electrical connections made through the metal pad and jet-dispensed dots may be preferred as compared to wire bonds or flip chip approaches, particularly for RF input and output signals. The use of jet-dispensed dots can also facilitate high-volume and automated process techniques.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1 illustrates an example assembly with an integrated circuit device and supporting substrate according to various examples described herein.

FIG. 2 is a top view of the integrated circuit device shown in FIG. 1 according to various examples described herein.

FIG. 3 is a bottom view of the integrated circuit device shown in FIG. 1 according to various examples described herein.

FIG. 4 is a bottom side view of the integrated circuit device shown in FIG. 1 according to various examples described herein.

FIG. 5 is another bottom side view of the integrated circuit device shown in FIG. 1 according to various examples described herein.

FIG. 6 illustrates the cross-sectional view of the integrated circuit device designated I-I in FIG. 1 according to various examples described herein.

FIG. 7 illustrates a process of hot via die attach jetting according to various examples described herein.

### DETAILED DESCRIPTION

A range of packages are available for integrated semiconductor circuit devices. Certain packages, packaging techniques, and device interconnection techniques may be better suited for high power and high frequency applications, and other considerations also factor into the selection of a particular package type and device interconnection approach. Some packages exhibit less intrinsic capacitance, inductance, and other parasitic characteristics, as examples, and those types of packages can be better suited for high power and high frequency applications.

A Monolithic Microwave Integrated Circuit (MMIC) device is one example of an integrated semiconductor circuit device. MMIC devices are implemented as integrated circuits formed on semiconductor substrates using semiconductor processing techniques. MMIC devices can incorporate active transistor amplifiers, in one or more amplifier stages, along with passive electrical components, integrated together in a single, monolithic format. The passive electrical components or devices can include Metal-Insulator-Metal (MIM) capacitors, resistors, transmission lines, inductors, RF couplers, and other integrated components. For ground connections and microstrip transmission effects, MMIC devices can also incorporate conductive ground planes formed on the bottom surfaces of MMIC substrates and vias that extend from the top to the bottom surfaces of the substrates. MMIC devices offer smaller feature sizes and better integration for components in radio frequency (RF) amplifier circuits and applications. Among others, the benefits of improved small signal performance, higher operating frequencies, larger operating bandwidths, and lower cost are attributed, at least in part, to the smaller feature sizes and high integration of MIMIC devices, particularly as compared to discrete hybrid implementations.

Certain packaging concerns are particular to MMIC devices. The improved small signal performance, higher operating frequencies, and larger operating bandwidths of MMIC devices can be attenuated or lost when using some packages. For example, the intrinsic inductance of wire bonds cannot be neglected, if a MIMIC device is packaged using wire bonds. Other disadvantages are attributed to flip chip packaging techniques. It can be more difficult to dissipate excess thermal energy and heat from MMIC devices in flip chip packaging approaches, particularly when MMIC devices include protective passivation layers over the components formed at the top side of the MIMIC substrates.

New approaches for interconnecting MIMIC and related integrated circuit devices are described herein. In one example, an integrated circuit device structure includes a semiconductor substrate, vias extending from a top to a bottom surface of the substrate, and a metal layer on the bottom surface of the substrate. The metal layer includes a metal pad extending around a via opening at the bottom surface of the substrate. The metal pad is electrically isolated from a remainder of the metal layer. The device structure also includes one or more jet-dispensed dots of a conductive die attach adhesive material on the metal pad. Electrical connections made through the metal pad and jet-dispensed dots may be preferred as compared to wire bonds or flip chip approaches, particularly for RF input and output signals. The use of jet-dispensed dots can facilitate high-volume and automated process techniques.

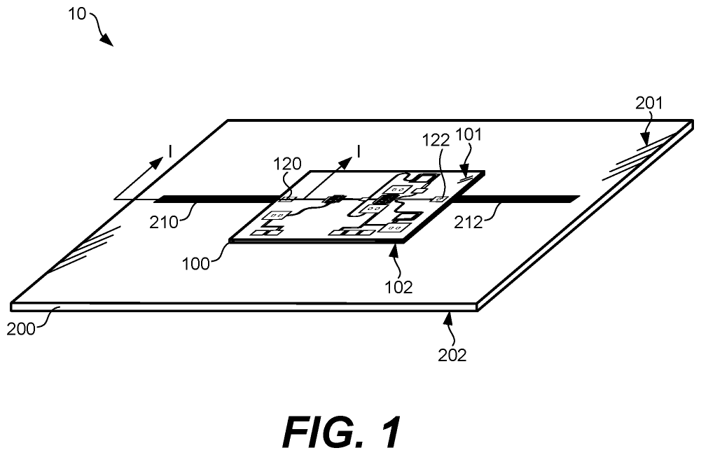

Turning to the drawings, FIG. 1 illustrates an example assembly 10 with an integrated circuit device 100 (also “IC device 100”) and supporting substrate 200 according to various examples described herein. The assembly 10 is provided as a representative example in FIG. 1. The shapes, sizes, and relative positions of the IC device 100 and the supporting substrate 200 are representative and may vary as compared to that shown. The IC device 100 and the supporting substrate 200 are also not drawn to any particular scale, and the concepts described herein are not limited to use with any particular integrated circuit devices or supporting substrates.

The IC device 100 is an integrated circuit device formed on a semiconductor material substrate or die. The semiconductor material substrate includes a top surface 101, a bottom surface 102, and a number of integrated circuit device components formed on, at, or over the top surface 101. In one example, the IC device 100 can be embodied as a MIMIC device for amplifying RF signals. The IC device 100 is not limited to any particular type of integrated semiconductor circuit device, however, as the concepts described herein can be applied to a range of integrated devices. Many, if not all, of the integrated circuit device components of the IC device 100 are formed on, at, or over the top surface 101 of the IC device 100. The IC device 100 also includes a conductive metal layer formed on, at, or over the bottom surface 102 in the examples described herein. Additional details related to IC device 100 are described below.

The IC device 100 is mounted on or over the supporting substrate 200. The supporting substrate 200 includes a top surface 201, bottom surface 202, and a number of metal traces formed on or over the top surface 201, among other features. The supporting substrate 200 can be embodied as a printed circuit board (PCB) including a number of conductive metal and laminated dielectric layers, a molded interconnect substrate, a metallized ceramic substrate, a flexible or film substrate, or another type of substrate. The supporting substrate 200 can be formed from a range of materials, including conductive metal layers, resins, ceramics, and other materials. The supporting substrate 200 can also include layers or components for the distribution of heat, such as relatively thick copper (Cu) layers, Cu filled vias, copper, molybdenum, or copper-molybdenum slugs and other features for heat distribution.

A primary purpose or function of the supporting substrate 200 is to provide electrical interconnects to the IC device 100. To that end, the supporting substrate 200 includes signal traces 212 and 214 on the top surface 201, for electrical interconnect with the IC device 100. The signal traces 212 and 214 are representative in FIG. 1, and the supporting substrate 200 may include additional metal traces that are not illustrated. In one example, the signal trace 212 can be relied upon as an RF input signal trace for the IC device 100, and the signal trace 214 can be relied upon as an RF output signal trace for the IC device 100. The supporting substrate 200 also supports the IC device 100 and, in some cases, provides a type of heat sink for the IC device 100. Additional aspects and features of the supporting substrate 200 are described below.

The IC device 100 includes a number of active devices, such as one or more transistor amplifiers, formed in or on the top surface 101 of the semiconductor material substrate. The IC device 100 also includes a number of passive electrical components or devices, such as capacitors, resistors, transmission lines, inductors, and other components, integrated together with the amplifiers in a monolithic format on the top surface 101. To that end, the IC device 100 can be embodied as an integrated RF MIMIC amplifier.

The IC device 100 includes electrical contacts for an RF input 120, an RF output 122, and other contacts for power, ground, and related connections. In the example shown, the RF input 120 of the IC device 100 is electrically coupled with the signal trace 210 on the substrate 200. Similarly, the RF output 122 of the IC device 100 is electrically coupled with the signal trace 212 on the substrate 200. The substrate 200 can also include a number of additional traces that are not illustrated in FIG. 1. The additional traces can be relied upon to facilitate other electrical connections with power, ground, and other connections to the IC device 100, as needed.

Due in part to the relatively small feature size of the amplifiers, passive components, and other features on the IC device 100, it can be challenging to establish electrical connections with the IC device 100 without interfering with the operation of the IC device 100 itself, among other tradeoffs. For example, establishing an electrical connection to a bond pad on the top surface of the IC device 100 (e.g., to a bond pad for the RF input 120 or output 122) using a bond wire would impart additional inductance, due to the intrinsic inductance of the bond wire itself. This inductance may change the operating characteristics of the IC device 100 for RF amplification. The inductance may change the operating frequency or bandwidth, the stability, or other operating characteristics of the RF amplifier in an unexpected or negative way. Alternatively, although flip chip packaging avoids the use of wire bonds, it may be more difficult to extract and disperse heat from the IC device 100 if it were flipped over and mounted with the top surface 101 of the IC device 100 facing the top surface 201 of the substrate 200.

According to aspects of the embodiments described herein, the electrical connections between the RF input 120 and output 122 of the IC device 100 and the signal traces 210 and 212 of the substrate 200, respectively, are accomplished using conductive plated vias that extend through the substrate of the IC device 100. The connections are also accomplished through the isolation of metal pads on the bottom surface 102 of the IC device 100 and the directed application of conductive die attach adhesive using jetting or jet dispensing techniques. The interconnection approaches described herein can also incorporate masks formed and pattered on the bottom surface 102 of the IC device 100 in some cases. The masks can help to isolate regions on the bottom surface 102 of the IC device 100, for the directed placement of conductive die attach adhesive through jetting or jet dispensing techniques. These and other aspects of the embodiments are described in further detail below.

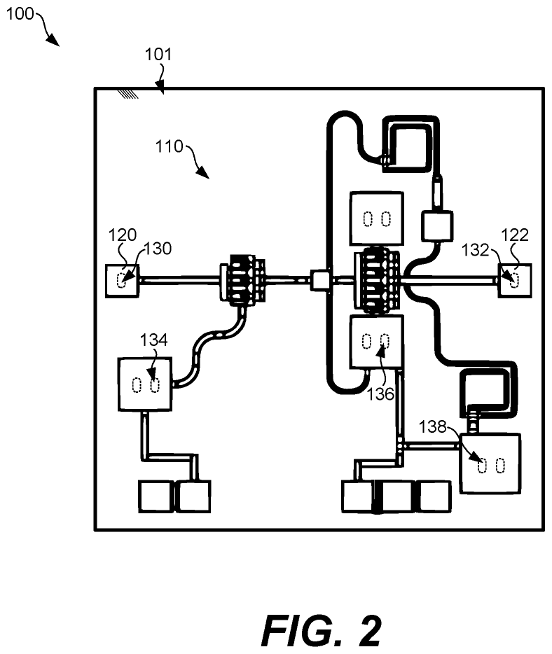

FIG. 2 is a top view of the IC device 100 shown in FIG. 1, and FIG. 2 is a bottom view of the IC device 100 shown in FIG. 1. As shown in FIG. 1, an RF amplifier 110 is formed on or over the top surface 101 of the IC device 100. The RF amplifier 110 can include one or more transistor amplifiers, transmission lines or interconnects, capacitors, resistors, inductors, and other components, integrated together in a monolithic format as a MIMIC amplifier of the IC device 100. The RF amplifier 110 is one example of the types of circuits that can be formed on the IC device 100, and the concepts described herein are not limited to use with any particular types of integrated circuit device or circuit.

The RF amplifier 110 is coupled between the RF input 120 and the RF output 122. The IC device 100 includes metal pads or features on the top surface 101, at the locations of the RF input 120 and the RF output 122. The IC device 100 also includes through-substrate vias 130 and 132, which extend from the top surface 101 to the bottom surface 102 of the substrate of the IC device 100. The via 130 is positioned under the metal pad for the RF input 120, and the via 132 is positioned under the metal pad for the RF output 122. As described in further detail below, the vias 130 and 132 provide electrical interconnects for the RF input 120 and RF output 122 of the IC device 100, through metal pads on the bottom surface 102 of the IC device 100.

The IC device 100 also includes additional through-substrate vias, including the vias 134, 136, and 138, among others. The vias 134, 136, and 138 also extend from the top surface 101 to the bottom surface 102 of the IC device 100. The vias 134, 136, and 138 are not relied upon for signal interconnects (e.g., RF input or output signals), however. The vias 134, 136, and 138 are relied upon to electrically connect metal traces and other features on the top surface 101 of the IC device 100 to a conductive metal ground plane layer on the bottom surface 102 of the IC device 100.

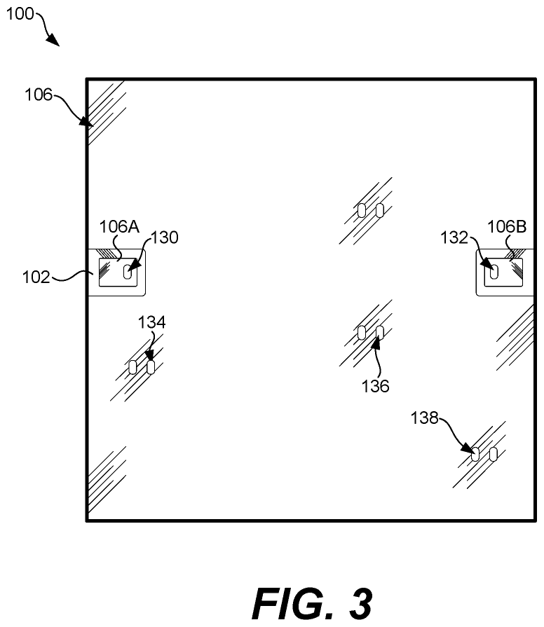

Referring to FIG. 3, the IC device 100 includes a metal layer 106 formed on the bottom surface 102 of the IC device 100. The metal layer 106 can be embodied as a conductive layer of metal, such as a layer of copper, other conductive metal, or metal alloy. The metal layer 106 provides a ground plane on the bottom surface 102 of the IC device 100. The vias 134, 136, and 138 extend from the top surface 101 to the bottom surface 102 of the IC device 100 and are electrically coupled to the metal layer 106. In some cases, a metal lining or layer is formed on the inner walls or surfaces of the vias 130, 132, 134, 136, and 138 when the metal layer 106 is formed. The metal layer 106 can be formed in any suitable way, such as by sputtering, other physical vapor deposition techniques, chemical vapor deposition techniques, plating techniques, and other materials processing techniques.

The metal layer 106 is also separated from other regions, areas, or pads of metal. As examples, the metal pads 106A and 106B are electrically separated from the metal layer 106. The metal pads 106A and 106B are shown as examples. Any number of metal pads, similar to the metal pads 106A and 106B, can be separate from the remainder of the metal layer 106. The sizes, shapes, and positions of the metal pads can vary as compared to the metal pads 106A and 106B.

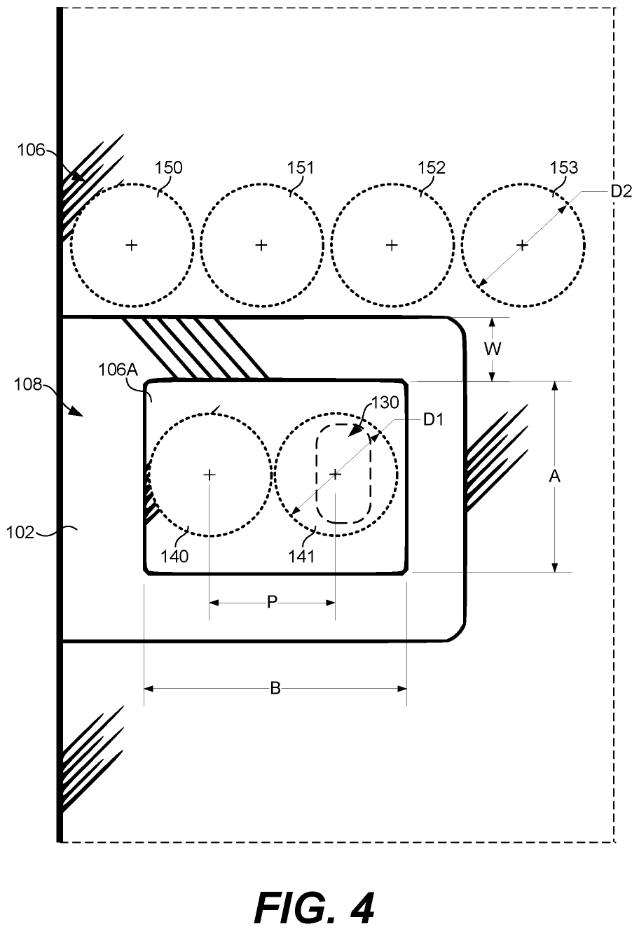

The metal pads 106A and 106B can be electrically separated from the metal layer 106. As one example, the metal layer 106 can be formed to extend over the bottom surface 102, or at least a portion of the bottom surface 102, of the IC device 100. The metal pads 106A and 106B can then be electrically separated from the metal layer 106 by masking and selectively etching away a region of conductive metal between the metal pads 106A and 106B and the remainder of the metal layer 106. Isolation streets can thus be formed between the metal pads 106A and 106B and the remainder of the metal layer 106, as described in further detail below with reference to FIG. 4. Alternatively, the metal pads 106A and 106B and the remainder of the metal layer 106 can be formed separately from each other, with isolation streets or regions between them. Other ways of separately forming or separating the metal pads 106A and 106B and the metal layer 106 are within the scope of the embodiments. The bottom surface 102 of the substrate of the IC device 100 can be exposed in the isolation areas or streets.

The vias 130 and 132 are electrically coupled with the metal pads 106A and 106B, respectively, but the vias 130 and 132 are electrically separated from the remainder of the metal layer 106. The vias 130 and 132 are also electrically separated from the vias 134, 136, and 138, among others, of the IC device 100. Thus, the vias 130 and 132 can be considered hot vias, because they are electrically separated from the metal layer 106 and the vias 134, 136, and 138, which are coupled to a common ground for the IC device 100.

Because the vias 130 and 132 are electrically separated from the remainder of the metal layer 106, the vias 130 and 132 can be relied upon as conductive interconnects for signals, including the RF input and output signals for the RF amplifier 110. When the IC device 100 is mounted over the supporting substrate 200, as shown in FIG. 1, the signal trace 210 of the supporting substrate 200 can be electrically coupled with the metal pad 106A of the IC device 100, as well as to the via 130. The signal trace 212 of the supporting substrate 200 can also be electrically coupled with the metal pad 106B and the via 132. In that way, the signal traces 210 and 212 on the supporting substrate 200, which carry RF input and output signals for the IC device 100, can be electrically coupled to the metal pads 106A and 106B and the vias 130 and 132 on the bottom of the IC device 100, as well as the RF input and output 120 and 122 pads and traces on the top of the IC device 100, respectively.

The metal pads 106A and 106B and vias 130 and 132 provide an interconnect approach that is preferable for certain applications of the IC device 100, as compared to other interconnect techniques. For example, the metal pads 106A and 106B and vias 130 and 132 have less intrinsic inductance than wire bonds. It is also unnecessary to flip the IC device 100 over when mounting and connecting it with the supporting substrate 200, as the RF input and output connections are made at the bottom of the IC device 100. Thus, the supporting substrate 200 can draw heat away from the bottom of the IC device 100, based on contact with the metal layer 106.

The electrical connections between the metal pads 106A and 106B and the signal traces 210 and 212, respectively, can be established using conductive die attach adhesive placed between them. The amount and particular placement of the conductive die attach adhesive can be a particular concern, due to the relatively small sizes of the metal pads 106A and 106B. It can also be a concern because of the small sizes of the isolation streets between the metal pads 106A and 106B and the metal layer 106. Technicians (i.e., individuals) have applied conductive die attach adhesive between MMIC devices and support or carrier substrates having small feature sizes in many cases, because many automated tooling systems lack the precision needed to apply the conductive die attach adhesive. Other methods, such as the automated placement of solder balls or bumps, may also be unsuitable for the feature sizes of the metal pads 106A and 106B, as many solder balls or bumps are too large and need a large spacing between solder ball and bumps. Solder balls and bumps are also not suitable to effectively dissipate heat to the substrate 200.

To address drawbacks with other die attach and packaging interconnect techniques, conductive die attach adhesive is applied using a jetting tool according to aspects of the embodiments. The jetting tool is capable of applying conductive die attach adhesives more precisely, at particular locations, and at dimensions and volumes for the small feature sizes of the metal pads 106A and 106B. Additionally, conductive die attach adhesives having a certain viscosity or viscosity range can be selected for use with the jetting nozzles needed for small feature sizes. The spacing or pitch between the dots can be tailored based on the size of the metal pads 106A and 106B, the inner diameter of the jetting nozzles, the viscosity of the conductive die attach adhesives, and other factors. Also, different jetting nozzles and pitch spacings can be used for the application of die attach adhesive to the metal pads 106A and 106B, as compared to the remainder of the metal layer 106 in some cases. These and other aspects are described below.

FIG. 4 is a detail bottom side view of part of the IC device 100 shown in FIG. 1. The features illustrated in FIG. 4 are not necessarily drawn to any particular scale or size, and the relative sizes of the features, with respect to each other, are not intended to limit the actual dimensions of the features. FIG. 4 is intended to provide context for the application of die attach adhesive(s) to MMIC and related IC devices using jetting tools, the application of die attach adhesive to metal pads or hot via pads using jetting tools, and related improvements.

FIG. 4 illustrates the metal layer 106 on the bottom surface 102 of the IC device 100, the metal pad 106A, and an isolation street 108 between the metal pad 106A and the remainder of the metal layer 106. The bottom surface 102 of the semiconductor substrate of the IC device 100 is exposed in the isolation street 108, in the example shown. The substrate of the IC device 100 may not be exposed in all cases, depending on whether or not additional layers are formed at the backside of the of the IC device 100. In any case, the metal pad 106A is electrically isolated from the remainder of the metal layer 106 by the isolation street 108. The isolation street 108 between the metal pad 106A and the remainder of the metal layer 106 can have a width “W” of about 100 μm in one example, although isolation streets of larger or smaller sizes can be relied upon in other cases.

The dimensions of the metal pad 106A, including the distance “B” along the length of the metal pad 106A and the distance “A” along the width of the metal pad 106A can also vary. Example length and width dimensions of the metal pad 106A can range from 300-1500 μm in length and from 300-1500 μm in width, although the metal pad 106A can be formed to other dimensions. In other examples, the length and width dimensions of the metal pad 106A can each be less than 500 μm, 600 μm, 700 μm, 800 μm, 900 μm, 1000 μm, 1100 μm, 1200 μm, 1300 μm, 1400 μm, 1500 μm, 2000 μm, 2500 μm, or 3000 μm, although the metal pad 106A can be larger in some cases. The metal pad 106A can also be formed to a shape other than rectangular or square, such as circular, oval, or other shapes. The metal pad 106B can be formed to similar sizes and shapes, as compared to the metal pad 106B.

FIG. 4 also illustrates a number of jet-dispensed dots 140, 141, and 150-153 (also “dots”). The dots 140, 141, and 150-153 are representative of regions in which conductive die attach adhesive has been applied at the bottom of the IC device 100s. The dots 140 and 141 are applied on the metal pad 106A, and the dots 150-153 are applied on the metal layer 106. The dots 140, 141, and 150-153 are applied by a jetting tool through a dispensing nozzle. The particular positions, sizes, and shapes of the dots are representative in FIG. 4. Dots of conductive die attach adhesive having other positions, sizes, and shapes are within the scope of the embodiments. Dots of conductive die attach adhesive similar to the dots 140 and 141 can also be formed on the metal pad 106B, as well as on other metal pads on the bottom of the IC device 100.

The dots 140 and 141 can be smaller, larger, or positioned at other locations on the metal pad 106A as compared to that shown. The dot 141 is shown as being positioned over the via 130 in FIG. 4, but the placement of dots over vias can be avoided in other cases. In some cases, certain design constraints or parameters can be imposed according to the concepts described herein. As one example, the minimum size of the metal pad 106A (i.e., “A”×“B”) can be set to no less than an area large enough to accommodate two dots, such as the dots 140 and 141, having a predetermined diameter “D1.” Alternatively, the minimum size of the metal pad 106A can be set to no less than an area large enough to accommodate three, four, five, or more dots having a predetermined diameter of some predetermined size.

Turning to the dots on the remainder of the metal layer 106, the dots 150-153 can be smaller, larger, or positioned at other locations on the metal layer 106 as compared to that shown. The dots 150-153 are representative of a subset of the dots that would typically be formed and positioned on the metal layer 106. The metal layer 106 can be substantially covered in dots of conductive die attach adhesive, to electrically and thermally couple the IC device 100 to the supporting substrate 200. The dispense dots can be overlapped in some cases to reduce or eliminate voiding between dots. In some cases, solder bumps or balls can be used between the metal layer 106 and the supporting substrate 200, rather than jet-dispensed dots, as the area of the metal layer 106 is significantly larger than that of the metal pads 106A and 106B.

The dots 140, 141, and 150-153 can be embodied as dots (e.g., blots, globs, or drops) of thermally- and electrically-conductive die attach adhesive, such as a thermoset epoxy carrier containing silver or other conductive material particles mixed in the carrier. The conductive die attach adhesive can be applied by a die attach jetting tool. The jetting tool can apply the conductive die attach adhesive through a dispensing nozzle, to form the dots 140, 141, and 150-153 in a regular shape. The inner diameter of the dispensing nozzle can vary depending on the size of the metal pad 106A, the viscosity of the conductive die attach adhesive being used, the desired size and height of the dots 140, 141, and 150-153, respectively, and related factors.

In some cases, two or more different types of nozzles or jetting tools can be relied upon to form the dots 140, 141, and 150-153, including nozzles of different sizes, shapes, types, and other characteristics. As one example, a first type of dispensing nozzle having a first inner diameter can be used to form the dots 140 and 141, and a second type of dispensing nozzle having a second inner diameter can be used to form the dots 150-153. The first inner diameter of the first nozzle can be smaller than the second inner diameter of the second nozzle. In that case the diameter “D1” of the dots 140 and 141 can be smaller than the diameter “D2” of the dots 150-153. In some cases, the dots 150-153 can be applied by a multi-tube or multi-nozzle dispensing tool, to increase the speed at which the dots 150-153 are formed, among others on the metal layer 106.

A number of competing factors can be considered in the selection of the type of die attach adhesive for the dots 140, 141, and 150-153, among others. Die attach adhesives having high thermal conductivity can be preferable to draw heat away from the IC device 100 to the supporting substrate 200. Die attach adhesives having lower viscosities can be preferable to create dots having small diameters, because dispensing nozzles having smaller inner diameters may clog if used with die attach adhesives having higher viscosities. Filler size is also an important factor to reduce clogging in dispensing nozzles. Filler size is related to the size of the particles, such as the metal particles contained in the carrier, in the die attach adhesive. A die attach adhesive including particles having a smaller filler size allow for a smaller diameter dispense nozzle and a smaller dispense dot while maintaining the same viscosity. Typically, however, the thermal conductivity of die attach adhesives is inversely related to the viscosity of the die attach adhesives. In other words, a die attach adhesive having a higher thermal conductivity will typically have a higher viscosity.

The die attach adhesive(s) used to form the dots 140, 141, and 150-153 can be selected by balancing competing concerns of thermal conductivity, viscosity, dot size, the potential for clogged dispensing nozzles, and related characteristics. As examples, the die attach adhesive used to form the dots 140 and 141, as well as other dots on metal pads, can have a viscosity of greater than 5 Pascal-second (Pass) and a thermal conductivity of greater than 1 Watts per meter-Kelvin (W/mK). The die attach adhesive used to form the dots 140 and 141 can have a viscosity of greater than 10 Pa·s and a thermal conductivity of greater than 50 W/mK in another example. The die attach adhesive used to form the dots 140 and 141 can have a viscosity of greater than 15 Pa·s and a thermal conductivity of greater than 100 W/mK in another example. The die attach adhesive used to form the dots 140 and 141 can have a viscosity of greater than 30 Pa·s and a thermal conductivity of greater than 125 W/mK in another example.

In other cases, the die attach adhesive used to form the dots 140 and 141 can have a viscosity of greater than 10, 20, 30, 40, or 50 Pa·s in other cases. The die attach adhesive used to form the dots 140 and 141 can also have a thermal conductivity of greater than 1, 2, 5, 10, 25, 50, 75, 100, 125, or 150 in other cases. Example die attach adhesives used to form the dots 140 and 141 include LOCTITE® ABLESTIK 84-1, ALPHA ATROX® 800HT5, ALPHA ATROX® HT2V, ALPHA ATROX® HT2VX, and NAMICS® UNIMEC XH9890-6AT, but the concepts described herein can be used with other types of die attach adhesives. The use of die attach adhesives having viscosities of less than 5 Pa·s and thermal conductivities of less than 1 can also be relied upon in some cases to form the dots 140 and 141, although a viscosity of greater than 5 Pa·s and a thermal conductivity of greater than 1 W/mK is preferred.

Additionally, the die attach adhesive used to form the dots 150-153 on the remainder of the metal layer 106, can have a viscosity of greater than 5 Pascal-second (Pass) and a thermal conductivity of greater than 1 Watts per meter-Kelvin (W/mK). The die attach adhesive used to form the dots 150-153 can have a viscosity of greater than 10 Pa·s and a thermal conductivity of greater than 50 W/mK in another example. The die attach adhesive used to form the dots 150-153 can have a viscosity of greater than 15 Pa·s and a thermal conductivity of greater than 100 W/mK in another example. The die attach adhesive used to form the dots 150-153 can have a viscosity of greater than 30 Pa·s and a thermal conductivity of greater than 125 W/mK in another example.

In other cases, the die attach adhesive used to form the dots 150-153 can have a viscosity of greater than 10, 20, 30, 40, or 50 Pa·s in other cases. The die attach adhesive used to form the dots 150-153 can also have a thermal conductivity of greater than 1, 2, 5, 10, 25, 50, 75, 100, 125, or 150 in other cases. Example die attach adhesives used to form the dots 150-153 include LOCTITE® ABLESTIK 84-1, ALPHA ATROX® 800HT5, ALPHA ATROX® HT2V, ALPHA ATROX® HT2VX, and NAMICS® UNIMEC XH9890-6AT, but the concepts described herein can be used with other types of die attach adhesives. The use of die attach adhesives having viscosities of less than 5 Pa·s and thermal conductivities of less than 1 can also be relied upon to form the dots 150-153 in some cases, although a viscosity of greater than 5 Pa·s and a thermal conductivity of greater than 1 W/mK is preferred.

In some cases, a first type of die attach adhesive can be used to form the dots 140 and 141, and a second type of die attach adhesive can be used to form the dots 150-153. The first type of die attach adhesive can be different than the second type of die attach adhesive. For example, the first type of die attach adhesive can have a lower viscosity than the second type of die attach adhesive. Alternatively, the second type of die attach adhesive can have a lower viscosity than the first type of die attach adhesive. The first type of die attach adhesive can have lower thermal conductivity than the second type of die attach adhesive, and other variations are within the scope of the embodiments.

The diameter “D1” of the dots 140 and 141 can be the same as the diameter “D2” of the dots 150-153 in some cases. In other cases, the diameter “D1” of the dots 140 and 141 can be smaller than the diameter “D2” of the dots 150-153, based on the use of jetting nozzles having different inner diameters, the placement of different amounts or volumes of die attach adhesive, and related factors. In still other cases, the diameter “D1” of the dots 140 and 141 can be larger than the diameter “D2” of the dots 150-153, based on the use of jetting nozzles having different inner diameters, the placement of different amounts or volumes of die attach adhesive, and related factors.

Each of the diameters “D1” and “D2” can be between 200-600 μm, between 250-550 μm, between 300-500 μm, or between 350-450 μm, and they can be different than each other. Particular sizes of the diameters “D1” and “D2” can be 200 μm, 250 μm, 300 μm, 350 μm, 450 μm, 500 μm, 550 μm, or 600 μm, among larger, smaller, and intermediate sizes. It should be appreciated that an intended or designed-for dimension of “D1” or “D2” may vary as compared to the actual size of the dots formed in practice using die attach jetting tools. For example, die attach adhesives having relatively lower viscosities may bleed or spread after being applied by the dispensing nozzle of the jetting tool, resulting in diameters or sizes larger than that expected. In practice, the tolerance or variation in the size of the “D1” and “D2” dimensions can range by about 5-25% of that expected depending on the viscosity of the die attach adhesive used and other factors.

As one example, an attempt to form dots having a diameter of 400 μm may result in a tolerance of 30 μm (e.g., range between 370 μm and 400 μm) among the dots. One factor in the size of the dots formed is the inner diameter of the jetting nozzles, and another factor is the amount of die attach adhesive jetted or expelled at a certain dot location. The ultimate sizes of the dots can vary based on other factors however, such as the temperature of the die attach adhesives when dispensed through the dispensing nozzle of the jetting tool, the ambient temperature, the amount of time elapsed after jetting, and other factors. Similarly, the pitch “P” between two dots, such as the dots 140 and 141, can be selected based on one or more factors, such as the inner diameter of the jetting nozzles used, the viscosity of the die attach adhesives used, the temperature of the die attach adhesives when dispensed through the dispensing nozzles, the ambient temperature, the amount of time elapsed after jetting, and other factors.

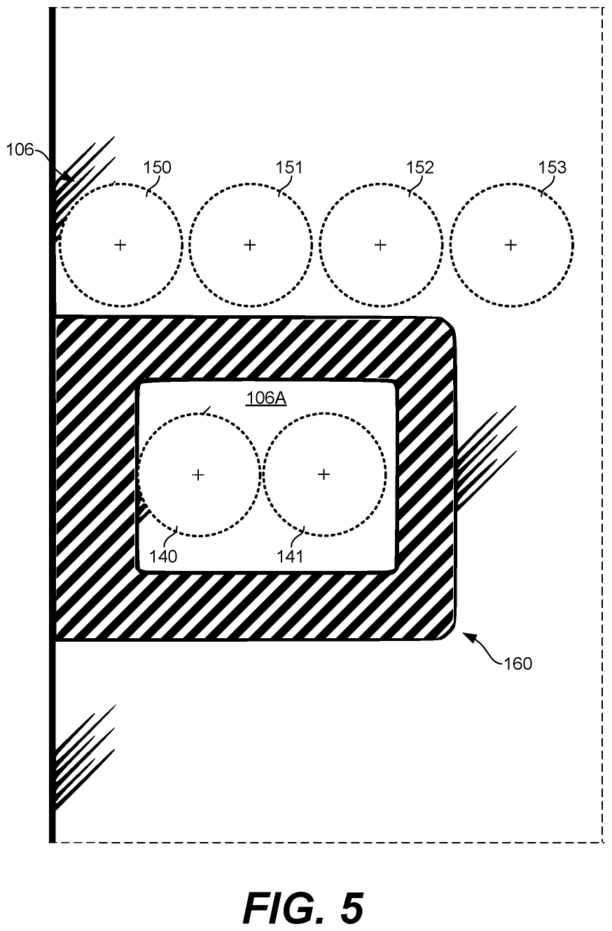

Turning to other aspects, FIG. 5 is another bottom side view of part of the IC device 100 shown in FIG. 1. In FIG. 5, the IC device 100 also includes a solder mask 160. The solder mask 160 extends over the isolation street 108 (see FIG. 4) between the metal pad 106A and the remainder of the metal layer 106. A similar (or the same) solder mask can also extend over the isolation street between the metal pad 106B and the remainder of the metal layer 106 (see FIG. 3). A solder mask can also be applied over the isolation streets of other metal pads that may be isolated from the remainder of the metal layer 106. When relied upon, the solder mask 160 can be applied to the bottom of the IC device 100 before any die attach material, solder bumps, or other material is applied to the bottom of the IC device 100.

In one example, the solder mask 160 does not cover (or does not intentionally cover) the metal pad 106A or the remainder of the metal layer 106. In another example, the solder mask 160 can partially overlap and cover the peripheral edges of the metal pad 106A, the edges of the metal layer 106 around the metal pad 106A, or both. The solder mask 160 can cover the peripheral edges of the metal pad 106A by between 1-10 μm, as measured starting from the peripheral edges of the metal pad 106A. Additionally or alternatively, the solder mask 160 can cover the peripheral edges of the metal layer 106 by between 1-10 μm, as measured starting from the peripheral edges of the metal layer 106 around the metal pad 106A.

The solder mask 160 can be embodied as a thin layer of epoxy or other polymer, although other materials suitable for use as a solder mask or solder damn can be relied upon. The solder mask 160 can be a liquid or dry-film photo-imageable mask, for example, and it can be sprayed, screened, or otherwise spread over the bottom of the IC device 100. In some cases, the solder mask 160 can be applied over only certain regions of the bottom of the IC device 100. The solder mask 160 can be photo-imaged using a photomask and cured using ultraviolet light, for example, or related photolithography techniques, to harden the region of the solder mask 160 shown in FIG. 5. Other areas or regions of the mask can then be removed. The solder mask 160 can help to avoid unintended electrical connections, such as solder bridges, between the metal pad 106A and the remainder of the metal layer 106.

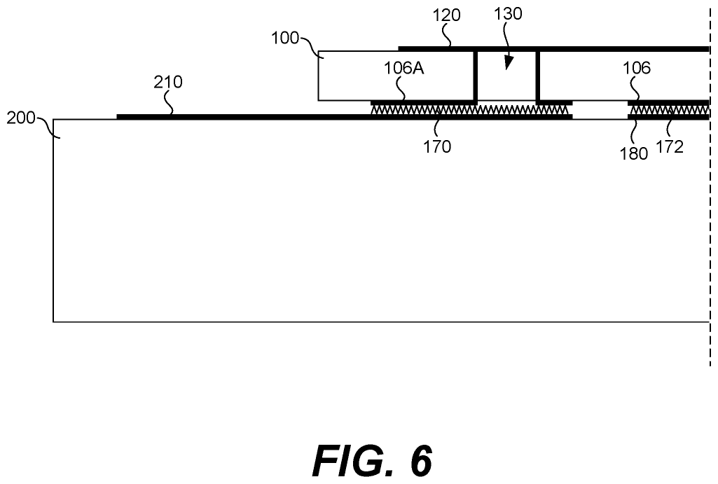

FIG. 6 illustrates the cross-sectional view of the IC device 100 designated I-I in FIG. 1. FIG. 6 illustrates how the metal pad 106A on the bottom of the IC device 100 is electrically coupled to the signal trace 210 on the supporting substrate. As shown, the die attach adhesive region 170 is cured between the metal pad 106A and the signal trace 210, electrically coupling or connecting them with each other. Thus, an RF input signal provided on the signal trace 210 will be electrically coupled to the metal pad 106A, through the via 130, and to the RF input 120 on the top of the IC device 100 (see also FIG. 1).

A die attach region 172 is also positioned between the metal layer 106 and a metal layer 180 of the supporting substrate 200. The die attach region 172 provides an electrical coupling between the metal layer 106 of the IC device 100 and a metal layer 180 of the supporting substrate 200, for ground, and also provides a type of heat sink, to draw away heat from the IC device 100.

The die attach adhesive region 170 is formed as a result of thermosetting or otherwise curing the dots 140 and 141 of conductive die attach adhesive (see FIG. 4), after the dots 140 and 141 are formed and the IC device 100 is positioned over the supporting substrate 200 as shown in FIG. 6. The dots 140 and 141 of conductive die attach adhesive can be cured in an oven, for example, based on the thermosetting profile for the conductive die attach adhesive, as described in further detail below, to form the die attach adhesive region 170. The die attach adhesive region 170 electrically couples the signal trace 210 to the metal pad 106A, which is electrically coupled to the via 130, and the RF input 120 on the top of the IC device 100. Thus, an RF signal provided on the signal trace 210 of the supporting substrate 200 can be coupled to the RF input 120 on the top of the IC device 100 without the need to use wire bonds. Additionally, the connection shown in FIG. 6 is formed without the need to flip the IC device 100 over, as part of a flip chip packaging process step.

The die attach region 172 is formed as a result of thermosetting or otherwise curing the dots 150-153 of conductive die attach adhesive (see FIG. 4), among others, after the dots 150-153 are formed and the IC device 100 is positioned over the supporting substrate 200 as shown in FIG. 6. The dots 150-153 of conductive die attach adhesive can be cured in an oven, for example, based on the thermosetting profile for the conductive die attach adhesive, as described in further detail below. In other cases, the die attach region 172 can be formed as a result of reflowing solder balls or bumps placed on the metal layer 106. The solder balls or bumps can be used in place of the dots 150-153 of conductive die attach adhesive in some cases.

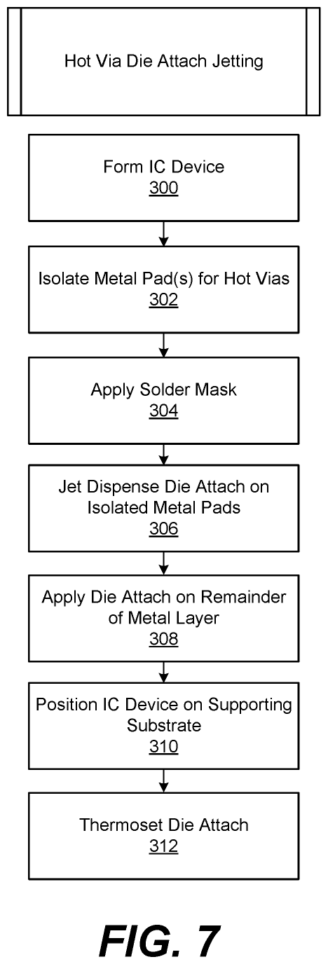

FIG. 7 illustrates a process of hot via die attach jetting according to various examples described herein. The process shown in FIG. 7 is described with reference to the IC device 100 described above. However, the process is not limited to use with any particular type of MMIC or related device, as the concepts of hot via die attach jetting can be applied to other devices. The process is not exhaustively illustrated, and other steps may be conducted or performed although they are not separately illustrated in FIG. 7. Additionally, one or more of the steps shown in FIG. 7 can be omitted in some cases, and one or more of the steps shown can be performed in an order that differs from that shown. For example, step 304 can be omitted in some cases, and the order of steps 306 and 308 can be reversed. Other variations on the sequence of steps shown in FIG. 7 are within the scope of the embodiments.

At step 300, the process includes forming or manufacturing an IC device, such as a MMIC device. For example, step 300 can include forming the IC device 100 using semiconductor processing or manufacturing techniques. The IC device 100 can be embodied as a MIMIC device for amplifying RF signals, but the concepts described herein can be applied to a range of integrated devices. Many of the integrated circuit device components of the IC device 100 are formed on, at, or over the top surface 101 of the IC device 100 as part of step 300.

As part of step 300, the process can also include forming one or more vias through the substrate of the IC device. The vias can extend from the top surface to the bottom surface of the substrate of the IC device. Referring to the IC device 100 as an example, it includes the through-substrate vias 130 and 132, which extend from the top surface 101 to the bottom surface 102 of the substrate of the IC device 100. The IC device 100 also includes additional through-substrate vias, including the vias 134, 136, and 138, among others. The vias 134, 136, and 138 also extend from the top surface 101 to the bottom surface 102 of the IC device 100.

As part of step 300, the process can also include forming a metal layer on the bottom surface of the substrate of the IC device and, in some cases, into the one or more vias. The metal layer 106, for example, can be formed on the bottom surface 102 of the IC device 100. The metal layer 106 can be embodied as a conductive layer of metal, such as a layer of copper, other conductive metal, or metal alloy. The metal layer 106 provides a ground plane on the bottom surface 102 of the IC device 100. A metal lining or layer can be formed on the inner walls or surfaces of the vias 130, 132, 134, 136, and 138 when the metal layer 106 is formed. The metal layer 106 can be formed in any suitable way, such as by sputtering, other physical vapor deposition techniques, chemical vapor deposition techniques, plating techniques, and other materials processing techniques.

At step 302, the process includes isolating one or more portions or areas of the metal layer formed at step 300, to form one or more isolated metal pads. As an example, the metal pads 106A and 106B of the IC device 100 can be isolated from the remainder of the metal layer 106. Any number of metal pads, similar to the metal pads 106A and 106B, can be isolated from the remainder of the metal layer 106. The sizes, shapes, and positions of the isolated metal pads can vary as compared to the metal pads 106A and 106B.

The metal pads 106A and 106B can be electrically separated and isolated from the metal layer 106 by masking and selectively etching away a region of conductive metal between them at step 302. Isolation streets are thus formed between the metal pads 106A and 106B and the remainder of the metal layer 106. The vias 130 and 132 are electrically coupled with the metal pads 106A and 106B, respectively, but the vias 130 and 132 are electrically separated from the remainder of the metal layer 106. The vias 130 and 132 are also electrically separated from the vias 134, 136, and 138, among others, of the IC device 100. Thus, the vias 130 and 132 can be considered hot vias, because they are electrically separated from the metal layer 106 and the vias 134, 136, and 138, which are coupled to a common ground for the IC device 100.

At step 304, the process includes applying and patterning a solder mask to the bottom of the IC device. As one example, the IC device 100 includes a solder mask 160, as shown in FIG. 5. The solder mask 160 extends over the isolation street 108 (see FIG. 4) between the metal pad 106A and the remainder of the metal layer 106. The solder mask can also extend over the isolation street between the metal pad 106B and the remainder of the metal layer 106. The solder mask can also be applied over isolation streets of other metal pads that are separated from the remainder of the metal layer 106. In some cases, step 304 can be omitted, and the process can continue without the application or use of a solder mask.

The solder mask 160 can be embodied as a thin layer of epoxy or other polymer, although other materials suitable for use as a solder mask or solder damn can be relied upon. The solder mask 160 can be a liquid or dry-film photo-imageable mask, for example, and it can be sprayed, screened, or otherwise spread over the bottom of the IC device 100. In some cases, the solder mask 160 can be applied over only certain regions of the bottom of the IC device 100. The solder mask 160 can be photo-imaged using a photomask and cured using ultraviolet light, for example, or related photolithography techniques, to harden the region of the solder mask 160 shown in FIG. 5. Other areas or regions of the mask can then be removed. The solder mask 160 can help to avoid unintended electrical connections, such as solder bridges, between the metal pad 106A and the remainder of the metal layer 106.

At step 306, the process includes jet dispensing one or more dots of conductive die attach adhesive on one or more of the metal pads that were isolated at step 302. As described above, FIG. 4 illustrates the jet-dispensed dots 140 and 141 of conductive die attach adhesive, which were applied on the metal pad 106A. Similar dots of conductive die attach adhesive can also be applied on the metal pad 106B at step 306. The dots 140 and 141 can be applied by a jetting tool. The jetting tool can apply the conductive die attach adhesive through a dispensing nozzle, to form the dots 140 and 141 in a regular shape. The inner diameter of the dispensing nozzle can vary depending on the size of the metal pad 106A, the viscosity of the conductive die attach adhesive being used, the desired size of the dots 140 and 141, and related factors described herein.

At step 308, the process includes jet dispensing one or more dots of conductive die attach adhesive on the remainder of the metal layer 106 on the bottom of the IC device 100. FIG. 4 illustrates the jet-dispensed dots 150-153 of conductive die attach adhesive, which were applied on the metal layer 106. The dots 150-153 can be applied by a jetting tool. The jetting tool can apply the conductive die attach adhesive through a dispensing nozzle, to form the dots 150-153 in a regular shape. The inner diameter of the dispensing nozzle can vary depending on the size of the metal layer 106, the viscosity of the conductive die attach adhesive being used, the filler size, the desired size of the dots 150-153, and related factors described herein.

In some cases, a first type of die attach adhesive can be used to form the dots 140 and 141 at step 306, and a second type of die attach adhesive can be used to form the dots 150-153 at step 308. The first type of die attach adhesive can be different than the second type of die attach adhesive. For example, the first type of die attach adhesive can have a lower viscosity than the second type of die attach adhesive. Alternatively, the second type of die attach adhesive can have a lower viscosity than the first type of die attach adhesive. The first type of die attach adhesive can have lower thermal conductivity than the second type of die attach adhesive, and other variations are within the scope of the embodiments.

In other cases, step 308 can include applying one or more solder bumps or balls on the metal layer 106, rather than the dots 150-153. The solder bumps or balls can be used in some cases, rather than jet-dispensed dots, as the area of the metal layer 106 is significantly larger than that of the metal pads 106A and 106B. The solder bumps or balls can be applied to adhered to the metal layer 106 using a tacky flux or other material to adhere the solder bumps for a period of time before solder reflow.

Step 310 includes positioning the IC device 100 over the supporting substrate 200, as substantially shown in FIGS. 1 and 6. The metal pads 106A and 106B can be aligned with the signal traces 212 and 214, respectively, on the top surface 201 of the substrate 200. At step 312, the process includes setting or thermosetting the dots of die attach adhesive that were dispensed on the bottom of the IC device 100 at steps 308 and 308. The thermosetting at step 312 can be performed in an oven, for example, based on the cure profile or profiles of the die attach adhesives used. The cure profile can include one or more temperature ramp-up periods, temperature soak periods, and temperature ramp-down periods, over respective periods of time. The thermosetting will flow, to some extent, and cure and harden the die attach adhesive. If solder balls or bumps are used on the metal layer 106, step 312 can include reflowing the solder balls or bumps based on heat from the oven, as would be understood in the field. Step 312 is not limited to thermosetting in an oven in all cases, however, as die attach adhesives can be thermoset in other ways. Step 312 is also not limited to setting or curing the die attach adhesives using heat, as some die attach adhesives can be cured or set by UV light or other approaches.

The features, structures, and components described above may be combined in one or more embodiments in any suitable manner, and the features discussed in the various embodiments are interchangeable, where technically suitable. In the foregoing description, numerous specific details are provided in order to fully understand the embodiments of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Although relative terms such as “on,” “below,” “upper,” “lower,” “top,” “bottom,” “right,” and “left” may be used to describe the relative spatial relationships of certain structural features, these terms are used for convenience only, as a direction in the examples. It should be understood that if the device is turned upside down, the “upper” component will become a “lower” component. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. An integrated circuit device, comprising:
a semiconductor substrate;
a plurality of vias extending from a top surface of the semiconductor substrate to a bottom surface of the semiconductor substrate;
a metal layer on the bottom surface of the semiconductor substrate, the metal layer comprising a metal pad extending around a via opening of one of the plurality of vias at the bottom surface of the semiconductor substrate, the metal pad being electrically isolated from a remainder of the metal layer at the bottom surface of the semiconductor substrate; and
a jet-dispensed dot of a conductive die attach adhesive material on the metal pad.

2. The integrated circuit device according to claim 1, wherein:
an isolation street extends between the metal pad and a remainder of the metal layer; and
the integrated circuit device further comprises a solder mask extending over at least part of the isolation street.

3. The integrated circuit device according to claim 1, further comprising a second jet-dispensed dot of a second conductive die attach adhesive material on the remainder of the metal layer.

4. The integrated circuit device according to claim 3, wherein the conductive die attach material of the jet-dispensed dot on the metal pad is different than the second conductive die attach material of the second jet-dispensed dot on the remainder of the metal layer.

5. The integrated circuit device according to claim 3, wherein a first diameter of the jet-dispensed dot on the metal pad is different than a second diameter of the second jet-dispensed dot on the remainder of the metal layer.

6. The integrated circuit device according to claim 3, wherein:
the jet-dispensed dot on the metal pad comprises a first plurality of jet-dispensed dots on the metal pad; and
the second jet-dispensed dot on the remainder of the metal layer comprises a second plurality of jet-dispensed dots on the remainder of the metal layer.

7. The integrated circuit device according to claim 1, further comprising a solder bump on the remainder of the metal layer.

8. The integrated circuit device according to claim 1, wherein the conductive die attach adhesive material has a viscosity of greater than 5 Pa·s and a thermal conductivity of greater than 1 W/mK.

9. A method for hot via coupling, comprising:
jet-dispensing a dot of a conductive die attach adhesive material on a metal pad of an integrated circuit device, the integrated circuit device comprising:
a semiconductor substrate;
a plurality of vias extending from a top surface of the semiconductor substrate to a bottom surface of the semiconductor substrate; and
a metal layer on the bottom surface of the semiconductor substrate, the metal layer comprising the metal pad extending around a via opening of one of the plurality of vias at the bottom surface of the semiconductor substrate, the metal pad being electrically isolated from a remainder of the metal layer at the bottom surface of the semiconductor substrate.

10. The method according to claim 9, further comprising jet-dispensing a second dot of the conductive die attach adhesive material on the remainder of the metal layer.

11. The method according to claim 9, further comprising jet-dispensing a second dot of a second conductive die attach adhesive material on the remainder of the metal layer.

12. The method according to claim 11, wherein the conductive die attach adhesive material of the dot on the metal pad is different than the second conductive die attach adhesive material of the second dot on the remainder of the metal layer.

13. The method according to claim 9, wherein jet-dispensing the dot comprises jet-dispensing a plurality of dots of the conductive die attach adhesive material on the metal pad.

14. The method according to claim 9, further comprising adhering a solder bump to the remainder of the metal layer.

15. The method according to claim 9, further comprising:
positioning the integrated circuit device over a supporting substrate, such that the metal pad of the integrated circuit device is aligned for an electrical connection to a trace on the supporting substrate; and
thermosetting the dot of a conductive die attach adhesive material.

16. A method for hot via coupling, comprising:
jet-dispensing a dot of a conductive die attach adhesive material on a metal pad of an integrated circuit device, the integrated circuit device comprising:
a metal layer on a bottom surface of a substrate, the metal layer comprising the metal pad extending around a via opening at the bottom surface of the substrate, the metal pad being electrically isolated from a remainder of the metal layer.

17. The method according to claim 16, further comprising jet-dispensing a second dot of the conductive die attach adhesive material on the remainder of the metal layer.

18. The method according to claim 16, further comprising:
jet-dispensing a second dot of a second conductive die attach adhesive material on the remainder of the metal layer, wherein
the conductive die attach adhesive material of the dot on the metal pad is different than the second conductive die attach adhesive material of the second dot on the remainder of the metal layer.

19. The method according to claim 16, wherein:
jet-dispensing the dot comprises jet-dispensing a first plurality of dots of the conductive die attach adhesive material on the metal pad; and
the method further comprises jet-dispensing a second plurality of dots of the conductive die attach adhesive material on the remainder of the metal layer.

20. The method according to claim 16, further comprising:
positioning the integrated circuit device over a supporting substrate, such that the metal pad of the integrated circuit device is aligned for an electrical connection to a trace on the supporting substrate; and
thermosetting the dot of a conductive die attach adhesive material.
